(19) United States
(12) Patent Application Publication
(10) Pub. No.: US 2025/0378237 A1
(43) Pub. Date: Dec. 11, 2025

(54) INFORMATION PROCESSING METHOD AND INFORMATION PROCESSING APPARATUS

(71) Applicant: Fujitsu Limited, Kawasaki-shi (JP)

(72) Inventors: Hiroaki KURIHARA, Chigasaki (JP); Ziyad OULHAJ, Nantes (FR); Yuichiro WADA, Setagaya (JP); Mutsuyo WADA, Funabashi (JP); Kento OHGA, Yokohama (JP); Kimihiro YAMAZAKI, Ohta (JP); Yoshiyuki ISHII, Kawasaki (JP); Takashi KATOH, Kawasaki (JP); Hiyori YOSHIKAWA, Kawasaki (JP); Mitsunori TOMA, Suginami (JP)

(73) Assignee: Fujitsu Limited, Kawasaki-shi (JP)

(21) Appl. No.: 19/228,788

(22) Filed: Jun. 5, 2025

(30) Foreign Application Priority Data
Jun. 10, 2024 (JP) 2024-093438

(51) Int. Cl. G06F 30/27

(52) U.S. Cl. CPC G06F 30/27

(57) ABSTRACT

A computer generates graph data including a plurality of nodes representing different features and a plurality of edges connecting the plurality of nodes in a latent space to which features each corresponding to shape data representing a shape of a molecule and having a smaller number of dimensions than the shape data belong. The computer calculates a weight for each of the plurality of edges, using the distance in the latent space between two nodes connected by the edge and a probability distribution of the features in the latent space. The computer predicts a deformation process between a first shape corresponding to a first node among the plurality of nodes and a second shape corresponding to a second node among the plurality of nodes by searching for a path in the latent space between the first node and the second node using the weights.

### CROSS-REFERENCE TO RELATED APPLICATION

This application is based upon and claims the benefit of priority of the prior Japanese Patent Application No. 2024-093438, filed on Jun. 10, 2024, the entire contents of which are incorporated herein by reference.

### FIELD

The embodiments discussed herein relate to an information processing method and an information processing apparatus.

### BACKGROUND

Molecules such as proteins may continuously deform over time under certain circumstances. A computer may need to simulate the natural deformation processes that a molecule is able to undergo. A machine learning model may be used for such a simulation.

For example, a prediction method of predicting a molecular deformation process using an autoencoder has been proposed. The encoder included in the autoencoder converts Fourier data representing a frequency component of a molecular image into a feature in a latent space. The decoder included in the autoencoder converts a feature in the latent space into Fourier data.

The proposed prediction method selects a feature at the start point from the latent space. The prediction method evaluates other features around the previous feature using their distances from the previous feature and the occurrence probabilities of the other features in the latent space. The prediction method selects the next feature from the vicinity of the previous feature using the evaluation results. By repeating the selection of the next feature, the prediction method determines a pathway from the start point to the end point in the latent space. The prediction method uses the decoder to convert a plurality of features on the pathway into a plurality of shapes that the molecule may take.

See, for example, Kimihiro Yamazaki, Yuichiro Wada, Atsushi Tokuhisa, Mutsuyo Wada, Takashi Katoh, Yuhei Umeda, Yasushi Okuno and Akira Nakagawa, “An Auto-Encoder to Reconstruct Structure with Cryo-EM Images via Theoretically Guaranteed Isometric Latent Space, and Its Application for Automatically Computing the Conformational Pathway,” Proc. of the 26th International Conference on Medical Image Computing and Computer Assisted Intervention (MICCAI 2023), pp. 394-404, October 2023

### SUMMARY

In one aspect, there is provided a non-transitory computer-readable storage medium storing a computer program that causes a computer to perform a process including: generating graph data including a plurality of nodes and a plurality of edges connecting the plurality of nodes in a latent space to which features each corresponding to shape data representing a shape of a molecule and having a smaller number of dimensions than the shape data belong, the plurality of nodes representing different features; calculating a weight for each edge of the plurality of edges, using a distance in the latent space between two nodes connected by the each edge and a probability distribution of the features in the latent space; and predicting a deformation process between a first shape corresponding to a first node among the plurality of nodes and a second shape corresponding to a second node among the plurality of nodes by searching for a path in the latent space between the first node and the second node using the weight.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram for describing an information processing apparatus according to a first embodiment;

FIG. 2 is a block diagram illustrating an example of hardware of an information processing apparatus;

FIG. 3 illustrates an example of a structure of a machine learning model;

FIG. 4 illustrates an example of a path search in a latent space;

FIG. 5 illustrates an example of shape changes corresponding to a path in the latent space;

FIG. 6 illustrates an example of a path search using a k-nearest neighbor graph;

FIG. 7 illustrates an example of a structure of a distance matrix;

FIG. 8 is a block diagram illustrating an example of functions of the information processing apparatus;

FIG. 9 is a flowchart illustrating a first example procedure for shape change prediction;

FIG. 10 is a flowchart illustrating a second example procedure for the shape change prediction;

FIG. 11 is a flowchart illustrating a third example procedure for the shape change prediction;

FIG. 12 illustrates an example of optimization of nodes on a line segment; and

FIG. 13 is a flowchart illustrating a fourth example procedure for the shape change prediction.

### DESCRIPTION OF EMBODIMENTS

The prediction method described in the aforementioned literature repeats local selection of selecting the next feature from the previous feature. Therefore, the path determined by repeating the local selection does not necessarily represent a natural deformation process from the shape of the start point to the shape of the end point, and there is room for improvement in the prediction accuracy for the deformation process.

Hereinafter, embodiments will be described with reference to the drawings. A plurality of embodiments may be implemented in combination.

### First Embodiment

An information processing apparatus 10 of a first embodiment predicts a deformation process in which a molecule such as a protein deforms from a specific shape to another shape, by using a machine learning model. The predicted deformation process may be used in various industrial fields such as drug development and material development. The information processing apparatus 10 may be a client apparatus or a server apparatus. The information processing apparatus 10 may be referred to as a computer, a machine learning device, or a simulation device.

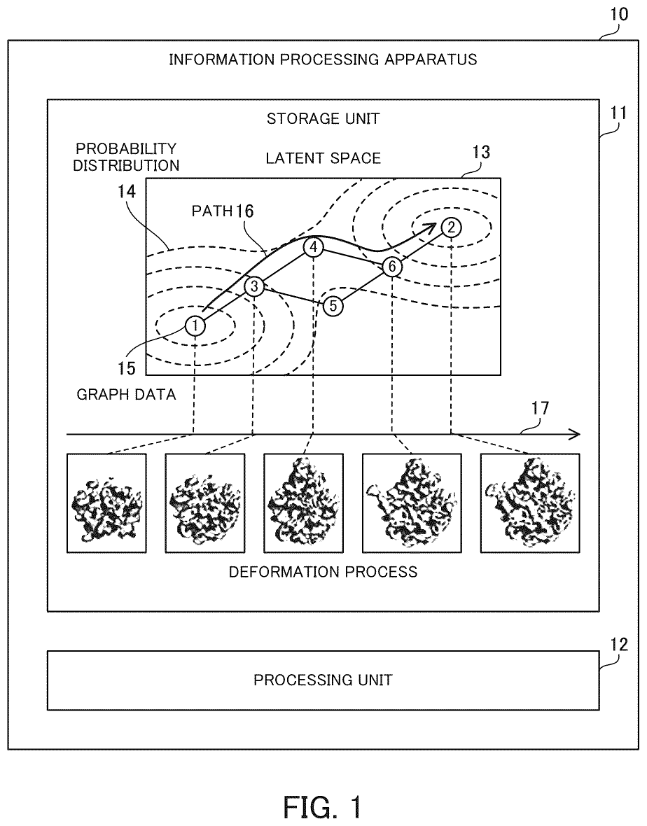

FIG. 1 is a diagram for describing the information processing apparatus according to the first embodiment. The information processing apparatus 10 includes a storage unit 11 and a processing unit 12. The storage unit 11 may be a volatile semiconductor memory such as a random access memory (RAM). The storage unit 11 may be a non-volatile storage device such as a hard disk drive (HDD) or a flash memory.

The processing unit 12 is, for example, a processor such as a central processing unit (CPU), a graphics processing unit (GPU), or a digital signal processor (DSP). However, the processing unit 12 may include an electronic circuit such as an application specific integrated circuit (ASIC) or a field programmable gate array (FPGA). The processor executes, for example, a program stored in a memory (which may be the storage unit 11) such as a RAM. The processor may be referred to as processor circuitry. A set of processors may be referred to as a multiprocessor or simply as a “processor”. Different processes among a plurality of processes to be described below may be executed by different processors.

The storage unit 11 stores graph data 15. The processing unit 12 generates the graph data 15 in a latent space 13. The latent space 13 is a space to which features corresponding to shape data representing shapes of a molecule and having a smaller number of dimensions than the shape data belong. The molecule may be a macromolecule or a biopolymer. Examples of molecules include proteins, ribonucleic acids (RNAs), sugars, lipids, etc.

The shape data may be image data representing a molecule, or may be cryo-image data captured by cryo-electron microscopy. The shape data may be three-dimensional model data representing a three-dimensional shape of a molecule. The features in the latent space 13 are, for example, eight-dimensional numerical vectors.

The storage unit 11 may store a trained machine learning model, or may store a machine learning model that maps a data space, to which shape data belongs, to the latent space 13. The machine learning model may be a neural network such as an autoencoder. The autoencoder includes an encoder and a decoder. For example, the encoder converts shape data or input data that is convertible from shape data into a feature in the latent space 13. The decoder converts a feature in the latent space 13 into shape data or output data that is convertible into shape data.

The autoencoder may be trained using a plurality of samples of shape data. The autoencoder may also be trained such that the features in the latent space 13 follow a probability distribution 14. The autoencoder may estimate the probability distribution 14 followed by the features in the latent space 13 through machine learning. The probability distribution 14 may be a single normal distribution or a Gaussian mixture distribution represented as a weighted sum of a plurality of normal distributions.

The latent space 13 preferably has isometricity. Isometricity includes the property that the distance between two features in the latent space 13 is proportional to the distance between two pieces of shape data corresponding to the two features. In addition, the isometricity includes the property that the occurrence probability of a feature in the latent space 13 is proportional to the occurrence probability of the shape data corresponding to the feature.

The graph data 15 includes a plurality of nodes representing different features and a plurality of edges connecting the plurality of nodes. The graph data 15 has edges between adjacent nodes having small distances. The graph data 15 may be a k-nearest neighbor graph (kNN graph). In the k-nearest neighbor graph, each node preferentially has edges to k neighbor nodes in ascending order of distance, and does not have edges to the other nodes.

The processing unit 12 may generate the graph data 15 by selecting a plurality of features as nodes from the latent space 13. In this case, the processing unit 12 may select the features based on the probability distribution 14. The features selected from the probability distribution 14 may include a feature corresponding to a peak indicating the maximum value of the probability, or may include features corresponding to respective peaks of the normal distributions forming a Gaussian mixture distribution. In addition, the processing unit 12 may randomly select features from the latent space 13 or may select features in a grid pattern at regular intervals.

The processing unit 12 may select a plurality of features corresponding to a plurality of samples of the shape data. The plurality of samples may have been used to train a machine learning model that maps a data space to a latent space. The processing 2 may calculate a plurality of features by inputting each of the plurality of samples to the encoder included in the autoencoder. In addition, the selected features may include a feature corresponding to the shape of the start point specified by a user or may include a feature corresponding to the shape of the end point specified by the user.

The processing unit 12 calculates a weight for each of the plurality of edges included in the graph data 15. The weight for an edge is calculated using the distance in the latent space 13 between the two nodes connected by the edge. The distance may be a Manhattan distance defined by the L1 norm or a Euclidean distance defined by the L2 norm. The weight is calculated using the probability distribution 14. The weight may be calculated using the probability of one or both of the two nodes connected by the edge. The weight may be calculated using the probability at the midpoint between the two nodes connected by the edge. The weight may be proportional to the distance and inversely proportional to the probability.

The processing unit 12 searches for a path 16 between one node and another node in the latent space 13 using the weights of the edges. The node at one end of the path 16 may be a start point specified by the user, and the node at the other end of the path 16 may be an end point specified by the user. Through the path search, the processing unit 12 predicts a deformation process 17 of the molecule. The deformation process 17 indicates continuous deformation from the shape indicated by the node at the one end to the shape indicated by the node at the other end, and indicates one or more intermediate shapes that the molecule may take during the deformation.

For example, the processing unit 12 searches the graph data 15 for the shortest path from the start node to the end node via one or more intermediate nodes. The shortest path search searches for a path that minimizes the sum of the weights of the edges traversed. The sum of the weights of the edges may be referred to as the maximum flux value. For the shortest path search, a path search algorithm such as Dijkstra's algorithm may be used. The path 16 may be the shortest path in the graph data 15.

In addition, the processing unit 12 may perform path optimization by starting with the shortest path in the graph data 15 and making fine adjustment to the positions of at least some nodes on the shortest path. For example, the processing unit 12 calculates, as a gradient, a change in the maximum flux value with respect to a change in the position of each node on the shortest path, and moves each node by a minute amount in the direction that decreases the maximum flux value. The path 16 may be an optimized path obtained in this way.

The processing unit 12 may predict the deformation process 17 by converting the features represented by one or more intermediate nodes included in the path 16 into shape data. At this time, the processing unit 12 may input the features to the decoder included in the autoencoder. The processing unit 12 may extract features other than nodes from the path 16 and convert the features into shape data. The deformation process 17 may be represented by arranging a plurality of shape data in time series. The processing unit 12 outputs the deformation process 17. At this time, the processing unit 12 may store the deformation process 17 in a non-volatile storage device, display the deformation process 17 on a display device, or transmit the deformation process 17 to another information processing apparatus.

As described above, the information processing apparatus 10 according to the first embodiment generates the graph data 15 in the latent space 13. The latent space 13 is a space to which features corresponding to shape data representing shapes of a molecule and having a smaller number of dimensions than the shape data belong. The graph data 15 includes a plurality of nodes representing different features and a plurality of edges connecting the nodes.

The information processing apparatus 10 calculates a weight for each edge, using the distance in the latent space 13 between the two nodes connected by the edge and the probability distribution 14 of the features in the latent space 13. The information processing apparatus 10 predicts the deformation process 17 between the first shape corresponding to a first node and the second shape corresponding to a second node by searching for the path 16 in the latent space 13 between the first node and the second node using the weights.

Accordingly, the information processing apparatus 10 is able to efficiently predict the deformation process 17 in which the molecule deforms from a certain shape to another shape. In addition, the user is able to obtain the deformation process 17 even if the user does not have extensive expertise in physics, chemistry, or biology, which reduces the burden on the user. In addition, the information processing apparatus 10 is able to facilitate drug discovery for developing new drugs by predicting the deformation process 17 for a biopolymer such as a protein.

In addition, the information processing apparatus 10 searches for the path 16 using the weights obtained in consideration of the probability distribution 14 in the latent space 13. Therefore, the path 16 approximates an ideal path that is calculated based on expert knowledge, and the quality of the predicted deformation process 17 is improved. The information processing apparatus 10 searches for the path 16 that is optimal from the viewpoint of the entire path, using the weighted graph data 15. Therefore, the quality of the deformation process 17 is improved as compared to the case of adopting local selection in which the next node is selected one by one, starting from a start node and moving toward an end node.

Note that the information processing apparatus 10 may convert a plurality of samples of the shape data into a plurality of features by using a trained autoencoder, and may generate the graph data 15 in which nodes represent the converted features. That is, the graph data 15 that includes a path close to an ideal path is generated in consideration of the distribution of the shape data. In addition, the graph data 15 may represent a k-nearest neighbor graph in which a plurality of nodes are each connected to k (k is an integer of 2 or more) other nodes in ascending order of distance. As a result, the number of edges is kept within a range sufficient for searching for the path 16, which reduces the cost of the path search.

The information processing apparatus 10 may search the graph data 15 for the shortest path that minimizes the sum of the weights of the edges traversed. Thereby, the path 16 close to an ideal path is efficiently derived. The information processing apparatus 10 may identify a first path from a first node to a second node via one or more third nodes, from the graph data 15. Further, the information processing apparatus 10 may generate a second path by moving at least some third nodes in the latent space 13 using the sum of the weights of the edges included in the first path. This further improves the search accuracy for the path 16 and the quality of the deformation process 17.

### Second Embodiment

An information processing apparatus 100 according to a second embodiment predicts a natural deformation process of a protein by using a machine learning model without relying on experiments. This deformation process represents, among continuous deformations of the same protein from one shape to another, a natural deformation from a physical, chemical or biological perspective. The predicted deformation process of the protein is used for, for example, drug development. The information processing apparatus 100 may be a client apparatus or a server apparatus. The information processing apparatus 100 corresponds to the information processing apparatus 10 of the first embodiment. In the second embodiment, the information processing apparatus 100 trains and uses the machine learning model. However, the training and use of the machine learning model may be performed by separate information processing apparatuses.

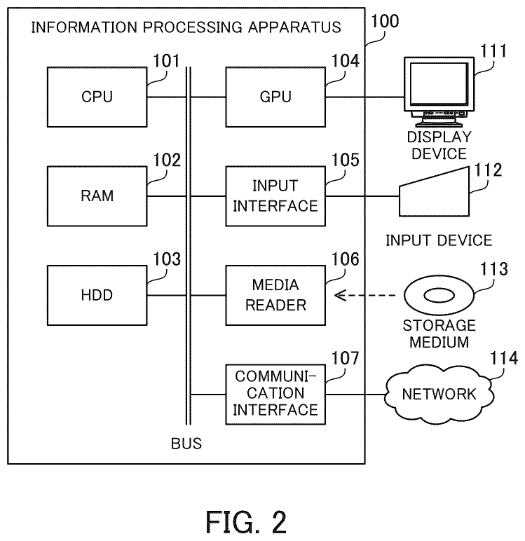

FIG. 2 is a block diagram illustrating an example of hardware of the information processing apparatus. The information processing apparatus 100 includes a CPU 101, a RAM 102, an HDD 103, a GPU 104, an input interface 105, a media reader 106, and a communication interface 107, which are connected to a bus. The CPU 101 corresponds to the processing unit 12 of the first embodiment. The RAM 102 or the HDD 103 corresponds to the storage unit 11 of the first embodiment.

The CPU 101 is a processor that executes instructions of a program. The CPU 101 loads a program and data stored in the HDD 103 into the RAM 102 and executes the program. The information processing apparatus 100 may include a plurality of processors.

The RAM 102 is a volatile semiconductor memory that temporarily stores a program to be executed by the CPU 101 and data to be used for calculation by the CPU 101. The information processing apparatus 100 may include types of volatile memory other than RAM.

The HDD 103 is a non-volatile storage device that stores software programs such as an operating system (OS), middleware, and application software, and data. The information processing apparatus 100 may include another type of non-volatile storage device such as a flash memory or a solid state drive (SSD).

The GPU 104 performs image processing in cooperation with the CPU 101, and outputs an image to a display device 111 connected to the information processing apparatus 100. The display device 111 is, for example, a cathode ray tube (CRT) display, a liquid crystal display, an organic electro luminescence (EL) display, or a projector. Another type of output device such as a printer may be connected to the information processing apparatus 100.

The GPU 104 may be used as a general purpose computing on graphics processing unit (GPGPU). The GPU 104 is able to execute a program in accordance with an instruction from the CPU 101. The information processing apparatus 100 may include a volatile semiconductor memory other than the RAM 102 as a GPU memory.

The input interface 105 receives an input signal from an input device 112 connected to the information processing apparatus 100. The input device 112 is, for example, a mouse, a touch panel, or a keyboard. A plurality of input devices may be connected to the information processing apparatus 100.

The media reader 106 is a reading device that reads a program and data recorded on a storage medium 113. The storage medium 113 is, for example, a magnetic disk, an optical disk, or a semiconductor memory. Magnetic disks include flexible disks (FDs) and HDDs. Optical discs include compact discs (CDs) and digital versatile discs (DVDs). The media reader 106 copies the program and data read from the storage medium 113 to another storage medium such as the RAM 102 or the HDD 103. The read program may be executed by the CPU 101.

The storage medium 113 may be a portable storage medium. The storage medium 113 may be used for distribution of programs and data. The storage medium 113 and the HDD 103 may be referred to as computer-readable storage media.

The communication interface 107 communicates with other information processing apparatuses via a network 114. The communication interface 107 may be a wired communication interface connected to a wired communication device such as a switch or a router, or may be a wireless communication interface connected to a wireless communication device such as a base station or an access point.

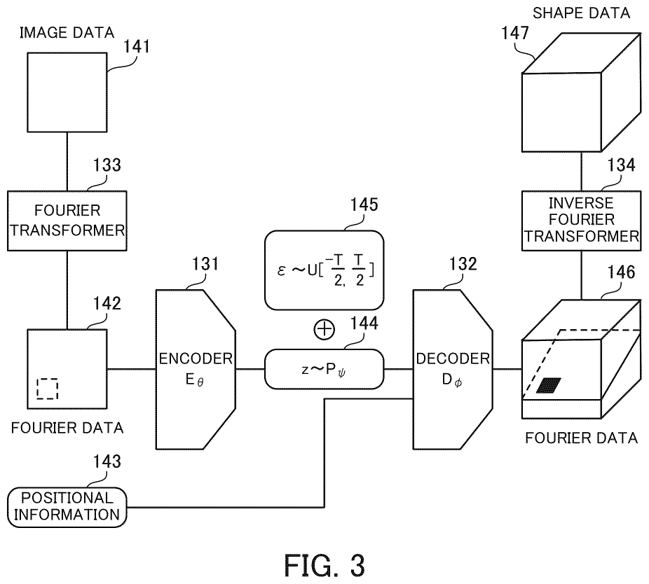

FIG. 3 illustrates an example of a structure of a machine learning model. The information processing apparatus 100 uses an autoencoder as a machine learning model. The information processing apparatus 100 may use an autoencoder called CryoTWIN described in the aforementioned literature. The autoencoder according to the second embodiment includes an encoder 131 and a decoder 132.

In the machine learning, the information processing apparatus 100 prepares image data 141. The image data 141 is cryo-image data obtained by imaging a protein from one direction using a cryo-electron microscope, and is two-dimensional image data. The information processing apparatus 100 prepares, as the image data 141, a plurality of pieces of image data obtained by imaging a protein having the same shape from different directions. In addition, the information processing apparatus 100 prepares, as the image data 141, a plurality of pieces of image data obtained by imaging proteins of the same type and different shapes.

The information processing apparatus 100 converts the image data 141 into Fourier data 142 by inputting the image data 141 to a Fourier transformer 133. The Fourier transformer 133 performs Fourier transform such as fast Fourier transform. The Fourier data 142 is two-dimensional data indicating a distribution of frequency components of the image data 141.

The information processing apparatus 100 initializes a parameter θ included in the encoder 131 and a parameter φ included in the decoder 132. The encoder 131 is a multilayer neural network including a plurality of layers. The parameter θ includes weights by which the input values of each layer are multiplied. Similarly, the decoder 132 is a multilayer neural network including a plurality of layers. The parameter φ includes weights by which the input values of each layer are multiplied.

The information processing apparatus 100 converts the Fourier data 142 into a feature 144 by inputting the Fourier data 142 to the encoder 131. The feature 144 is a numerical vector belonging to a latent space. The number of dimensions of the feature 144 is smaller than that of the Fourier data 142, and is, for example, eight dimensions. The machine learning includes ψ estimating a probability distribution P_{ψ} that the feature 144 follows. The probability distribution P_{ψ} is a Gaussian mixture distribution having a parameter ψ. The parameter ψ includes the mean and standard deviation of each of the plurality of normal distributions and the weight of each normal distribution.

The information processing apparatus 100 adds noise 145 to the feature 144. The noise 145 is a random number selected from the range of a uniform distribution having a constant width T. Accordingly, in the latent space, a feature is extracted again from the vicinity of the feature 144. In the machine learning, the latent space is learned to follow a specific probability distribution, by adding the noise 145 to the feature 144.

Further, the information processing apparatus 100 generates positional information 143 corresponding to the Fourier data 142. The positional information 143 indicates a direction in which the protein is imaged in the three-dimensional space. In addition, the positional information 143 indicates a region of interest in the Fourier data 142. The information processing apparatus 100 may calculate three-dimensional coordinates as the positional information 143 by applying a rotation angle to the two-dimensional coordinates on the Fourier data 142.

The information processing apparatus 100 predicts some frequency components included in Fourier data 146, by inputting the feature 144 having the noise 145 added thereto and the positional information 143 to the decoder 132. The Fourier data 146 is three-dimensional data indicating frequency components obtained by performing Fourier transform on the three-dimensional shape of the protein. The decoder 132 predicts the frequency components at the position indicated by the positional information 143. The information processing apparatus 100 fixes the feature 144 and repeatedly uses the decoder 132 while changing the region of interest in the Fourier data 142. The information processing apparatus 100 generates prediction data corresponding to the Fourier data 142 by arranging the frequency components predicted by the decoder 132 on a plane.

The information processing apparatus 100 compares the prediction data with the Fourier data 142 to calculate the error. The information processing apparatus 100 repeats the error calculation while changing the image data 141. Then, the information processing apparatus 100 updates the parameters θ, ϕ, and ψ using the backpropagation method so as to reduce the overall error. At this time, the information processing apparatus 100 fits the features 144 corresponding to the various image data 141 to the Gaussian mixture distribution to update the probability distribution P_{ψ}. The information processing apparatus 100 updates the parameter φ of the decoder 132 and updates the parameter θ of the encoder 131, based on the updated probability distribution P_{ψ}. The information processing apparatus 100 iteratively updates the parameters θ, φ, and ψ.

In this way, the information processing apparatus 100 trains the autoencoder including the encoder 131, which converts the Fourier data 142 into the feature 144, and the decoder 132, which converts the feature 144 into the Fourier data 146. The information processing apparatus 100 learns the probability distribution P_{ψ} in the latent space to which the feature 144 belongs.

The information processing apparatus 100 is able to generate various shapes that a protein is able to take by using the trained decoder 132. When the autoencoder is used, the information processing apparatus 100 selects a feature 144 from the latent space and generates positional information 143. The information processing apparatus 100 predicts frequency components included in Fourier data 146 by inputting the feature 144 and the positional information 143 to the decoder 132. The information processing apparatus 100 fixes the feature 144 and repeatedly uses the decoder 132 while changing the region of interest and the angle indicating the imaging direction. Thus, the entire Fourier data 146 is generated.

The information processing apparatus 100 converts the Fourier data 146 into shape data 147 by inputting the Fourier data 146 to an inverse Fourier transformer 134. The inverse Fourier transformer 134 performs inverse Fourier transform such as inverse fast Fourier transform. The shape data 147 is three-dimensional density data indicating the three-dimensional shape of the protein. One piece of shape data 147 corresponds to one feature 144 included in the latent space.

The latent space learned by such an autoencoder has isometricity expressed by Expression (1). In Expression (1), z and z′ are features in the latent space, V_{z} is shape data corresponding to the feature z, and V_{z}′ is shape data corresponding to the feature z′. Further, P_{ψ}(z) is the occurrence probability of the feature z in the latent space, and P(V_{z}) is the occurrence probability of the shape data V_{z} in the data space. The isometricity includes the property that the distance between the features z and z′ in the latent space is proportional to the distance between the shape data V_{z} and V_{z}′ in the data space. The isometricity also includes the property that the occurrence probability of the feature z in the latent space is proportional to the occurrence probability of the shape data V_{z} in the data space.

$$‖ z - {z}^{′} ‖ ∝ ‖ {V}_{z} - {V}_{{z}^{′}} ‖ ∧ {P}_{ψ} ( z ) ∝ ( {V}_{z} ) \qquad ( 1 )$$

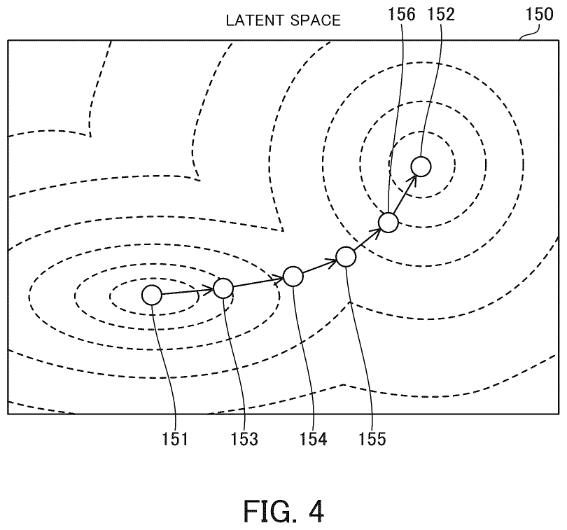

FIG. 4 illustrates an example of a path search in a latent space. The information processing apparatus 100 predicts natural shape changes of a protein by using a trained autoencoder. The information processing apparatus 100 searches for a path starting from a node 151 and reaching a node 152 in the latent space 150. The node 151 is a start node and represents a feature corresponding to the shape at the deformation start time point specified by the user. The node 152 is an end node and represents a feature corresponding to the shape at the deformation end time point specified by the user.

The information processing apparatus 100 may receive the feature at the start point and the feature at the end point from the user. Alternatively, the information processing apparatus 100 may receive image data representing the shape at the deformation start time point from the user, and convert the image data into a feature by using the encoder 131. Similarly, the information processing apparatus 100 may receive image data representing the shape at the deformation end time point from the user, and convert the image data into a feature by using the encoder 131.

The information processing apparatus 100 identifies a path passing through nodes 153, 154, 155, and 156. The nodes 153, 154, 155, and 156 are intermediate nodes and represent features corresponding to shapes that the protein may take in the deformation process. In this path, the node 153 follows the node 151, the node 154 follows the node 153, the node 155 follows the node 154, the node 156 follows the node 155, and the node 152 follows the node 156.

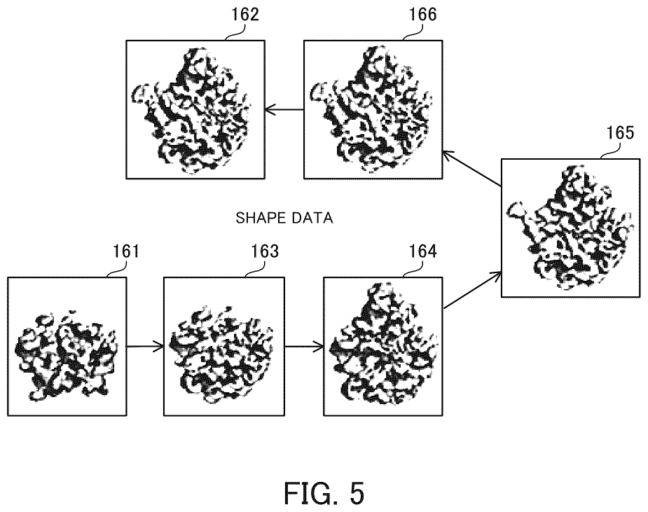

FIG. 5 illustrates an example of shape changes corresponding to a path in the latent space. By using the decoder 132, the information processing apparatus 100 predicts intermediate shapes that the protein is able to take, from the features included in the path in the latent space 150.

The shape data 161 corresponds to the node 151 and represents the shape of the protein at the start point. The shape data 162 corresponds to the node 152 and represents the shape of the protein at the end point. The shape data 163, 164, 165, and 166 represents intermediate shapes of the protein. The shape data 163 corresponds to the node 153, the shape data 164 corresponds to the node 154, the shape data 165 corresponds to the node 155, and the shape data 166 corresponds to the node 156. The information processing apparatus 100 outputs the shape data 161, 162, 163, 164, 165, and 166.

Here, it is preferable that the deformation process predicted by the information processing apparatus 100 is reasonable from a physical, chemical, or biological perspective. In this respect, the quality of the predicted deformation process depends on the accuracy of the path search in the latent space. The following describes a path search method. As one path search method, the information processing apparatus 100 may adopt local selection in which the next node is selected in the direction of the lowest cost from the previous node.

Here, it is assumed that the information processing apparatus 100 selects K+1 features from the latent space. A feature z₀ is a start point, and a feature z_{K} is an end point. This path passes through features zₖ (k=1, 2, . . . , K−1) between the feature z₀ and the feature z_{K}.

In order to obtain a natural path, it is preferable that the value of Expression (2) is large. Expression (2) represents the sum of the occurrence probabilities of the K+1 features in the latent space. P_{ψ} is a probability distribution estimated in the latent space through training of the autoencoder. In addition, in order to obtain a natural path, it is preferable that the value of Expression (3) is small. Expression (3) represents the sum of the Euclidean distances between adjacent features.

$${{\sum }^{K}}_{k = 0} {P}_{ψ} ( {z}_{k} ) \qquad ( 2 )$$

$${\sum }_{k = 0}^{K - 1} {‖ {z}_{k + 1} - {z}_{k} ‖}_{2} \qquad ( 3 )$$

Procedurally, it is conceivable that the information processing apparatus 100 selects the next feature one by one, starting from the start point and moving toward the end point, according to Expression (4). When the (k−1)-th feature Zₖ₋₁ is determined, the information processing apparatus 100 selects M feature candidates from the vicinity of the feature Zₖ₋₁. The M candidates may be selected at random or may be selected in a grid pattern at regular intervals. The information processing apparatus 100 calculates the occurrence probability of each candidate from the probability distribution P_{ψ} and calculates the Euclidean distance between the feature Zₖ₋₁ and each candidate.

$${z}_{k} = arg {min}_{{z}^{( m )}} \frac{{P}_{ψ} ( {z}_{0} )}{{P}_{ψ} ( {z}^{( m )} )} {‖ {z}^{( m )} - {z}_{k - 1} ‖}_{2} , m = 1 , … , M \qquad ( 4 )$$

The information processing apparatus 100 calculates, for each candidate, a cost that is proportional to the Euclidean distance and inversely proportional to the occurrence probability. The information processing apparatus 100 selects the candidate having the minimum cost among the M candidates as the k-th feature zₖ. The information processing apparatus 100 repeats selecting the feature zₖ from the vicinity of the feature Zₖ₋₁ until reaching the end point. As a result, the information processing apparatus 100 identifies the path represented by Expression (5). Here, μᵢ is the feature at the start point, and μⱼ is the feature at the end point. The information processing apparatus 100 converts the path into a shape data string represented by Expression (6).

$${μ}_{i} = {z}_{0} \to {z}_{1} \to {z}_{2} \to … \to {z}_{K - 1} \to {z}_{K} = {μ}_{j} \qquad ( 5 )$$

$${V}_{{μ}_{i}} = {V}_{{z}_{0}} \to {V}_{{z}_{1}} \to … \to {V}_{{z}_{K - 1}} \to {V}_{{z}_{K}} = {V}_{{μ}_{j}} \qquad ( 6 )$$

By evaluating the features using the probability distribution in the latent space, intermediate features having higher occurrence probabilities are more likely to be selected, so that intermediate shapes having higher occurrence probabilities are more likely to be generated. However, in the local selection as described above, the entire path from the start point to the end point is not necessarily optimized, and there is room for improvement in the quality of the shape data string. Therefore, in the second embodiment, the information processing apparatus 100 optimizes the entire path using a graph search described below.

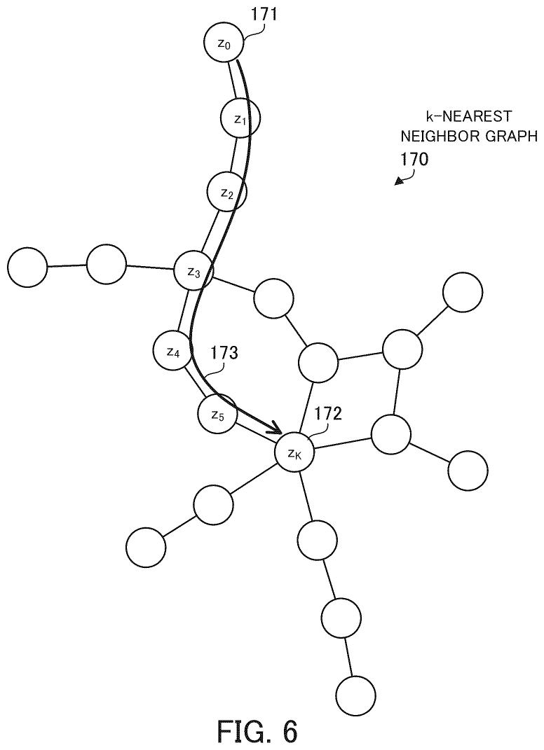

FIG. 6 illustrates an example of a path search using a k-nearest neighbor graph. The information processing apparatus 100 generates a k-nearest neighbor graph 170 defined in a latent space. The k-nearest neighbor graph 170 includes a plurality of nodes representing different features and a plurality of edges connecting the nodes. The k-nearest neighbor graph 170 includes a node 171 representing the feature at the start point and a node 172 representing the feature at the end point. In addition to the nodes 171 and 172, the k-nearest neighbor graph 170 includes n (n is an integer of 2 or more) nodes. For example, n is approximately 100,000.

Regarding the start point and the end point, the information processing apparatus 100 may receive the specification of the nodes 171 and 172 from the user. Alternatively, the information processing apparatus 100 may acquire image data representing the shape at the start point and image data representing the shape at the end point from the user, and may convert the image data into the nodes 171 and 172 by using the encoder 131.

For the n nodes other than the start point and the end point, the information processing apparatus 100 may acquire n samples of image data representing different shapes of the same type of protein, and may convert the n samples into n nodes by using the encoder 131. The acquired samples may be those used for training the autoencoder. The information processing apparatus 100 may randomly select n nodes from the latent space in accordance with a probability distribution estimated in the latent space by machine learning.

The information processing apparatus 100 calculates the Euclidean distances between n+2 nodes. For each node, the information processing apparatus 100 identifies k other nodes in ascending order of Euclidean distance. k is sufficiently smaller than n, and for example, k is approximately 10 to 20. The information processing apparatus 100 connects the node to the k other nodes by edges. The node is not directly connected to the remaining distant nodes. In this way, the k-nearest neighbor graph 170 is generated. The k-nearest neighbor graph 170 is an undirected graph in which neighbor nodes are connected by edges, and is a single connected graph in which any two nodes are reachable from each other via one or more edges.

The information processing apparatus 100 calculates the weight dᵢⱼ of Expression (7) for an edge included in the k-nearest neighbor graph 170. The weight dᵢⱼ is a weight between the node i and the node j, and may be referred to as a weighted distance. The weight dᵢⱼ is proportional to the Euclidean distance between the node i and the node j. The weight dᵢⱼ is inversely proportional to the occurrence probability at the midpoint between the node i and the node j. The information processing apparatus 100 calculates a feature corresponding to the midpoint between the node i and the node j, and obtains a probability corresponding to the feature from a probability distribution P_{ψ} estimated by machine learning.

$${d}_{ij} = \frac{1}{{P}_{ψ} ( \frac{{z}_{i} + {z}_{j}}{2} )} {‖ {z}_{i} - {z}_{j} ‖}_{2} \qquad ( 7 )$$

It is also said that the information processing apparatus 100 corrects the Euclidean distance using the probability distribution P_{ψ}. The weight dᵢⱼ approximates the transition probability of two protein shapes corresponding to two adjacent features, and reflects physical, chemical, or biological knowledge. A smaller weight dᵢⱼ indicates that a shape change is more likely to occur.

The information processing apparatus 100 uses the k-nearest neighbor graph 170 in which the edges are weighted, to search for the shortest path that minimizes the value of a cost function among the paths starting from the node 171 and reaching the node 172. In the second embodiment, the sum of the weights of the edges traversed is used as the cost function. The sum of the weights of the edges may be referred to as the maximum flux value. The information processing apparatus 100 executes a path search algorithm such as Dijkstra's algorithm. In FIG. 6, a path 173 from the node 171 to the node 172 via five intermediate nodes is identified. The information processing apparatus 100 converts the nodes on the path 173 into shape data by using the decoder 132, and outputs a shape data string in which the shape data is arranged in time series.

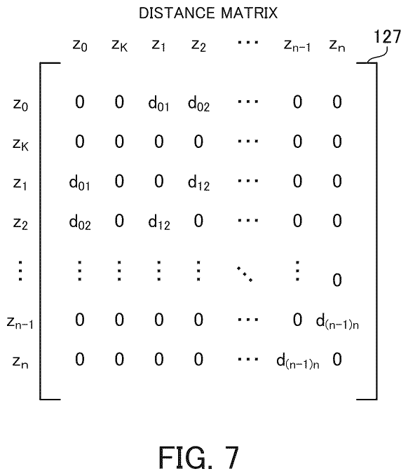

FIG. 7 illustrates an example of a structure of a distance matrix. In the graph search described above, the information processing apparatus 100 uses a distance matrix 127. The distance matrix 127 is a square matrix in which the length of one side corresponds to the number of nodes. The information processing apparatus 100 calculates the Euclidean distance between the node i and the node j, and records the Euclidean distance in the i-th row and j-th column of the distance matrix 127.

Next, the information processing apparatus 100 retains k components in ascending order of numerical value in each row or column, and replaces the remaining components with zero. A zero value in the i-th row and j-th column indicates that the node i and the node j are not connected by an edge. Then, the information processing apparatus 100 replaces the non-zero components of the distance matrix 127 with the weights dᵢⱼ of Expression (7). In the case where the component in the i-th row and j-th column is not zero, the information processing apparatus 100 calculates the occurrence probability of the midpoint between the node i and the node j, and divides the existing component in the i-th row and j-th column by the occurrence probability. The information processing apparatus 100 searches for the shortest path using the distance matrix 127 generated in this manner.

Here, the quality of the shape data string identified by the shortest path on the k-nearest neighbor graph 170 will be supplementarily described. In Expression (8), S^{(N)}K indicates a path having the minimum maximum flux value among paths determined by selecting K nodes from a graph including N nodes. In Expressions (8) and (9), SK indicates a path having the minimum maximum flux value among paths determined by selecting K nodes from the entire latent space. In Expression (9), S* indicates a path that is considered optimal from expert knowledge.

$${lim}_{N \to ∞} {S}_{K}^{( N )} = {S}_{K} \qquad ( 8 )$$

$${lim}_{K \to ∞} {S}_{K} = {S}^{*} \qquad ( 9 )$$

When the number K of nodes in the path is fixed and the number N of nodes in the graph is increased one by one, the number of path candidates increase monotonically. Due to the property of the weight dᵢⱼ between nodes, the maximum flux value of the path S^{(N)}K after the number N of nodes is increased is either equal to or smaller than the maximum flux value before the number N of nodes is increased.

The maximum flux value of the path S^{(N)}K is a positive number. Therefore, as seen in Expression (8), by sufficiently increasing the number of nodes N in the graph, the path S^{(N)}K converges to the path SK that is obtained in the case where the node positions are not constrained.

Further, it is considered that the number K of nodes in a path is increased one by one by inserting a new node between two adjacent nodes in the path. The position of the new node is determined such that the maximum flux value is minimized. By inserting a new node between two nodes, the partial path connecting the two nodes may change from a straight line to a curved line. Due to the property of the weight dᵢⱼ between nodes, the maximum flux value of the path Sk after the number K of nodes is increased is either equal to or smaller than the maximum flux value before the number K of nodes is increased.

The maximum flux value of the path SK is a positive number. Therefore, as seen in Expression (9), the path SK converges to the ideal path S* by sufficiently increasing the number K of nodes in the path. From Expressions (8) and (9), the shortest path obtained from the k-nearest neighbor graph 170 in which the number n of samples is sufficiently large approximates an optimal path. Next, the functions and processing procedures of the information processing apparatus 100 according to the second embodiment will be described.

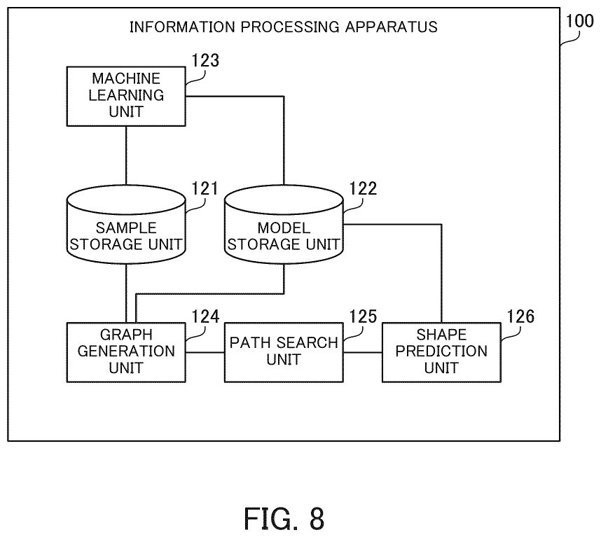

FIG. 8 is a block diagram illustrating an example of functions of the information processing apparatus. The information processing apparatus 100 includes a sample storage unit 121, a model storage unit 122, a machine learning unit 123, a graph generation unit 124, a path search unit 125, and a shape prediction unit 126. The sample storage unit 121 and the model storage unit 122 are implemented using, for example, the RAM 102 or the HDD 103. The machine learning unit 123, the graph generation unit 124, the path search unit 125, and the shape prediction unit 126 are implemented using, for example, the CPU 101, the GPU 104, and a program.

The sample storage unit 121 stores samples of image data representing shapes of proteins. The model storage unit 122 stores a trained autoencoder. The autoencoder includes the encoder 131 and the decoder 132. Further, the model storage unit 122 stores information on a probability distribution P_{ψ} estimated in the latent space by machine learning.

The machine learning unit 123 trains the autoencoder by the backpropagation method using the samples stored in the sample storage unit 121. The parameter θ of the encoder 131, the parameter φ of the decoder 132, and the parameter ψ of the probability distribution P_{ψ} are optimized by the machine learning. The machine learning unit 123 stores the values of the parameters θ, φ, and ψ in the model storage unit 122.

The graph generation unit 124 receives the specification of the shape of a start point and the shape of an end point. The graph generation unit 124 generates a graph including a plurality of nodes representing different features in the latent space by using the samples stored in the sample storage unit 121. However, the graph generation unit 124 may generate the graph by randomly selecting features according to the probability distribution P_{ψ}. In the second embodiment, a k-nearest neighbor graph is generated. The graph generation unit 124 calculates a weight for each of the plurality of edges included in the graph using the probability distribution P_{ψ}.

The path search unit 125 searches the latent space for a path that minimizes the value of a cost function using the graph generated by the graph generation unit 124. In the second embodiment, the cost function represents the maximum flux value that is the sum of the weights of the edges traversed. In the second embodiment, the path search unit 125 searches for the shortest path from the graph.

The shape prediction unit 126 converts the nodes included in the path identified by the path search unit 125 into shape data by using the decoder 132. However, the shape prediction unit 126 may convert features other than the nodes on the graph into shape data as long as the features are on the path. The shape prediction unit 126 outputs a shape data string in which the shape data is arranged in time series from the start point to the end point. The shape prediction unit 126 may store the shape data string in a non-volatile storage device, may display the shape data string on the display device 111, or may transmit the shape data string to another information processing apparatus.

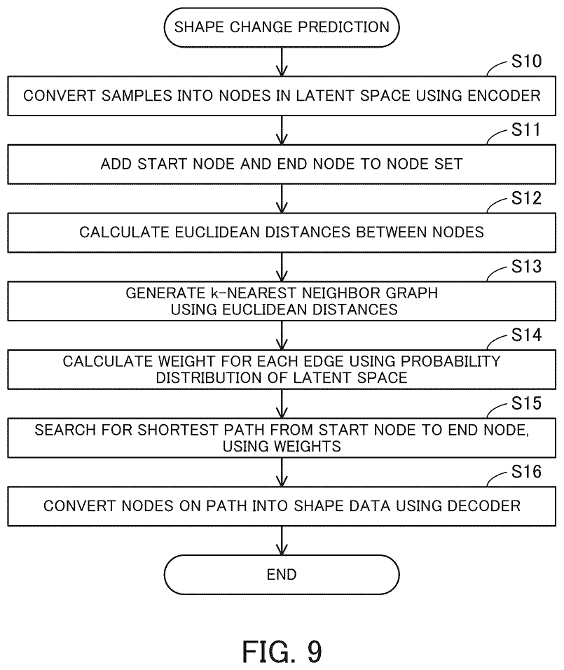

FIG. 9 is a flowchart illustrating a first example procedure for shape change prediction. In step S10, the graph generation unit 124 converts n samples into n nodes in a latent space by using the encoder 131. In step S11, the graph generation unit 124 adds a start node indicating the shape of a start point and an end node indicating the shape of an end point to the node set obtained in step S10. As a result, a node set including the n+2 nodes is obtained.

In step S12, the graph generation unit 124 calculates the Euclidean distances between the nodes. In step S13, the graph generation unit 124 generates a k-nearest neighbor graph from the node set using the Euclidean distances. In the k-nearest neighbor graph, each node is connected to k neighbor nodes in ascending order of Euclidean distance by edges.

In step S14, the graph generation unit 124 calculates a weight for each edge included in the k-nearest neighbor graph using the probability distribution of the latent space. The weight is calculated by dividing the Euclidean distance by the occurrence probability of the feature corresponding to the midpoint of the edge.

In step S15, the path search unit 125 searches for the shortest path from the start node to the end node on the k-nearest neighbor graph in which the edges are weighted. The shortest path is a path that minimizes the maximum flux value, which is the sum of the weights of the edges traversed. In step S16, the shape prediction unit 126 converts each feature represented by the nodes included in the shortest path in step S15 into shape data by using the decoder 132. The shape prediction unit 126 outputs a shape data string in which the converted shape data is arranged in time series.

As described above, the information processing apparatus 100 according to the second embodiment predicts and visualizes a deformation process in which a protein changes from a certain shape to another shape, by using a machine learning model. This provides useful information for industrial fields such as drug development. In addition, the user may acquire information on the protein deformation process without additional experiments even if the user does not have extensive expertise in physics, chemistry, or biology.

In addition, the information processing apparatus 100 searches for a path in consideration of a probability distribution in a latent space given by the autoencoder, and converts the path into a shape data string. The latent space has isometricity in which distances in the latent space are and the proportional to distances in the data space occurrence probability of a feature in the latent space is proportional to the occurrence probability of shape data in the data space. Accordingly, the predicted deformation process approximates an ideal deformation process that is derived based on expert knowledge, and the prediction accuracy is improved. In addition, the deformation process of the protein is efficiently predicted.

In addition, the information processing apparatus 100 generates a k-nearest neighbor graph including a large number of nodes in the latent space, and assigns, to each edge, a weight that is proportional to the Euclidean distance and inversely proportional to the occurrence probability. The information processing apparatus 100 searches the k-nearest neighbor graph for the shortest path that minimizes the maximum flux value. Accordingly, optimization is performed from the viewpoint of the entire path, and the prediction accuracy is improved. Further, by increasing the number of nodes in the k-nearest neighbor graph, the shortest path approximates a theoretically optimal path. In addition, by limiting the edges to between neighbor nodes, the calculation amount of the path search is reduced.

### Third Embodiment

A third embodiment is different from the second embodiment in the path search method in a latent space. Hereinafter, matters different from those of the second embodiment will be mainly described, and description of matters similar to those of the second embodiment may be omitted.

An information processing apparatus according to the third embodiment may be implemented using the same hardware as in FIG. 2. The information processing apparatus according to the third embodiment is able to use the same autoencoder as that illustrated in FIG. 3. The information processing apparatus according to the third embodiment may be implemented with the same functional blocks as those in FIG. 8. Therefore, the third embodiment will be described below using the same reference numerals as those in FIGS. 2, 3, and 8.

In the second embodiment, the shortest path obtained from a k-nearest neighbor graph is adopted as a final path as it is. In this regard, since the number of nodes to be given is finite, there is a possibility that the maximum flux value decreases when a path slightly deviated from the shortest path of the k-nearest neighbor graph is traced. On the other hand, when the number of nodes in the k-nearest neighbor graph is excessively increased, the calculation amount of the path search increases. Therefore, in the third embodiment, the information processing apparatus 100 performs path optimization to finely adjust the positions of nodes with reference to the shortest path obtained from the k-nearest neighbor graph.

The information processing apparatus 100 defines a cost function for the shortest path of the k-nearest neighbor graph. The cost function according to the third embodiment represents the maximum flux value that is the sum of the weights between adjacent nodes on a path. Each weight is calculated as in Expression (7) described above. When one node included in the path is moved in the latent space, both the Euclidean distance and the occurrence probability of the midpoint change in relation to its adjacent nodes. As a result, the value of the cost function changes. Therefore, the cost function is a function whose value changes depending on the positions of the nodes included in the path.

The information processing apparatus 100 calculates the gradient of the cost function value for each of the nodes other than the start point and the end point. A gradient indicates a change amount of the cost function value when the position of a node is moved by a minute amount in the latent space. The gradient may be referred to as a derivative of the cost function value. The information processing apparatus 100 moves the nodes other than the start point and the end point in the direction that decreases the cost function value. The information processing apparatus 100 may determine the movement amount according to the magnitude of the gradient.

The information processing apparatus 100 searches for a path that minimizes the cost function value in the latent space, by iteratively moving a node. This path is not constrained to the shape of the original k-nearest neighbor graph. The information processing apparatus 100 may iteratively move a node a certain number of times, or may iteratively move a node until the cost function value converges.

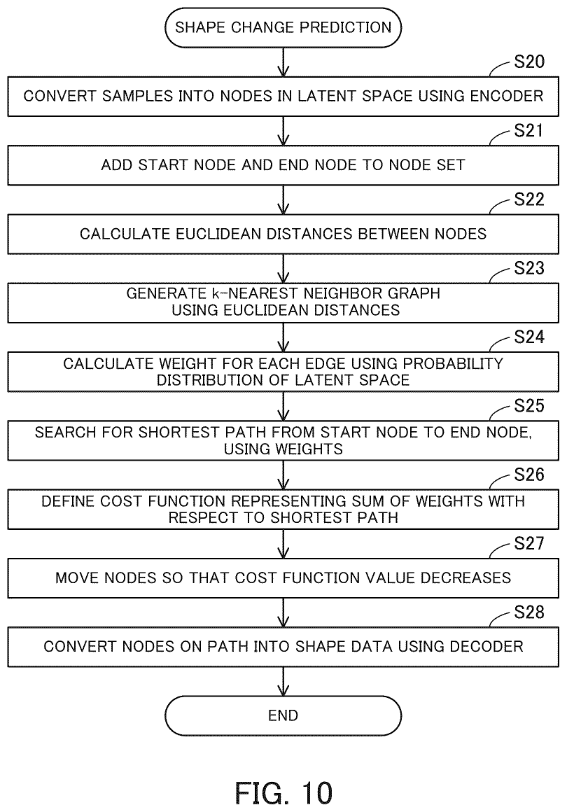

FIG. 10 is a flowchart illustrating a second example procedure for the shape change prediction. In step S20, the graph generation unit 124 converts n samples into n nodes in a latent space by using the encoder 131. In step S21, the graph generation unit 124 adds a start node indicating the shape of a start point and an end node indicating the shape of an end point to the node set obtained in step S20. Further, the graph generation unit 124 identifies a peak feature in which the probability has a maximum value from the probability distribution in the latent space. The graph generation unit 124 adds a certain number of peak nodes representing peak features in descending order of probability to the node set obtained in step S20. For example, the certain number is 30. As a result, a node set including the n+32 nodes is obtained.

In step S22, the graph generation unit 124 calculates the Euclidean distances between the nodes. In step S23, the graph generation unit 124 generates a k-nearest neighbor graph from the node set using the Euclidean distances. In step S24, the graph generation unit 124 calculates a weight for each edge included in the k-nearest neighbor graph using the probability distribution of the latent space. In step S25, the path search unit 125 searches for the shortest path from the start node to the end node on the k-nearest neighbor graph in which the edges are weighted.

In step S26, the path search unit 125 defines a cost function having the positions of the nodes included in the shortest path in step S25 as parameters. The cost function represents the maximum flux value that is the sum of weights between adjacent nodes. In step S27, the path search unit 125 moves a node included in the path so that the cost function value decreases, using the gradient of the cost function value with respect to the position of the node. The path search unit 125 iteratively moves a node until the cost function value converges.

In step S28, the shape prediction unit 126 converts each feature represented by the nodes included in the path optimized in step S27 into shape data by using the decoder 132. The features of the nodes after the optimization are the features at the positions after the movement, and may be different from any feature represented by the nodes included in the k-nearest neighbor graph at the time of step S23. The shape prediction unit 126 outputs a shape data string in which the converted shape data is arranged in time series.

As described above, the third embodiment has the same effects as those of the second embodiment. Further, the information processing apparatus 100 according to the third embodiment optimizes the shortest path obtained from the k-nearest neighbor graph by finely adjusting the positions of the nodes included in the shortest path. Thus, a path having a smaller maximum flux value is found, and the prediction accuracy for a deformation process is improved.

### Fourth Embodiment

A fourth embodiment is different from the second and third embodiments in the path search method in a latent space. Hereinafter, matters different from those of the second and third embodiments will be mainly described, and description of matters similar to those of the second and third embodiments may be omitted.

An information processing apparatus according to the fourth embodiment may be implemented using the same hardware as in FIG. 2. The information processing apparatus according to the fourth embodiment is able to use the same autoencoder as that illustrated in FIG. 3. The information processing apparatus according to the fourth embodiment may be implemented with the same functional blocks as those in FIG. 8. Therefore, the fourth embodiment will be described below using the same reference numerals as those in FIGS. 2, 3, and 8.

In the third embodiment, the shortest path obtained from a k-nearest neighbor graph is used as a reference, and nodes on the shortest path are moved without being constrained to the k-nearest neighbor graph, thereby finding a path having a smaller maximum flux value. However, since this approach releases the connectivity constraints of the k-nearest neighbor graph, there is a risk that the finally obtained path may be an unnatural path deviated from the structure of the k-nearest neighbor graph. The unnatural path is, for example, a meandering path that temporarily returns toward the start point before reaching the end point, a path in which the order of nodes is substantially changed, or the like.

To address this, in the fourth embodiment, the information processing apparatus 100 adds a constraint term that suppresses deviation from the structure of the k-nearest neighbor graph, to a cost function. The constraint term may be referred to as a penalty term. The cost function represents the sum of the maximum flux value of the path and the constraint term. Expression (10) represents the constraint term. E is a set of edges included in the k-nearest neighbor graph. λ is a hyperparameter for adjusting the magnitude of the constraint term, and the value thereof is specified by the user.

λΣ_{(i,j)∈E}∥f(zᵢ)−f(zⱼ)∥₂² (10)

In order to calculate the constraint term, the information processing apparatus 100 defines a function f that gives a real number to each node included in the k-nearest neighbor graph. The function f converts the features in the latent space into scalar values. For example, the function f calculates a function value from the components included in a numerical vector that is a feature. It is preferable that similar real numbers are obtained from similar features.

For each edge included in the k-nearest neighbor graph, the constraint term calculates the square of the difference between the value of the function f of one node and the value of the function f of the other node. The constraint term calculates the sum of the squares of the differences from all the edges included in the k-nearest neighbor graph. In the case where a node included in the shortest path obtained from the k-nearest neighbor graph is moved, the constraint term is calculated using the position after the movement. When a node movement greatly changes the graph structure from the original k-nearest neighbor graph, the constraint term of Expression (10) increases, and the cost function value increases. As a result, such a node movement that greatly changes the graph structure from the original k-nearest neighbor graph is suppressed.

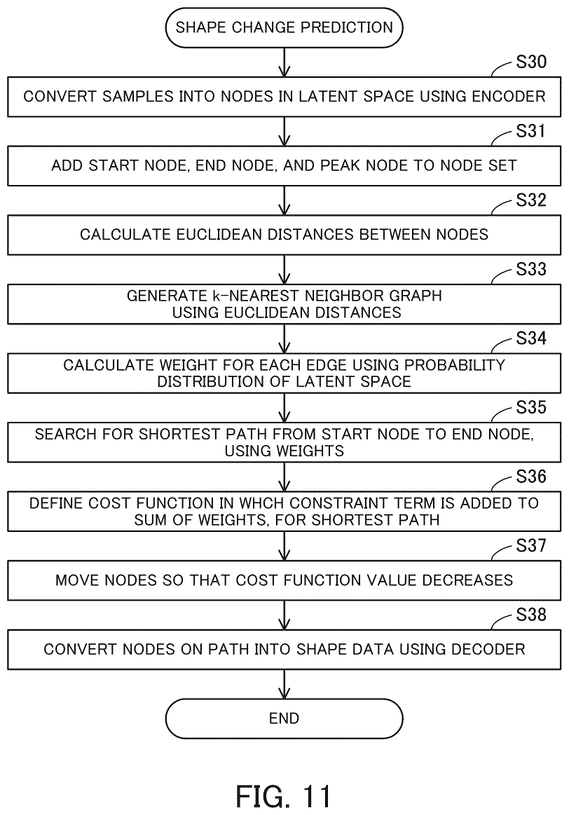

FIG. 11 is a flowchart illustrating a third example procedure for the shape change prediction. In step S30, the graph generation unit 124 converts n samples into n nodes in a latent space by using the encoder 131. In step S31, the graph generation unit 124 adds a start node indicating the shape of a start point and an end node indicating the shape of an end point to the node set obtained in step S30. Further, the graph generation unit 124 identifies a peak feature in which the probability has a maximum value from the probability distribution of the latent space. The graph generation unit 124 adds a certain number of peak nodes representing peak features in descending order of probability to the node set obtained in step S30.

In step S32, the graph generation unit 124 calculates the Euclidean distances between the nodes. In step S33, the graph generation unit 124 generates a k-nearest neighbor graph from the node set using the Euclidean distances. In step S34, the graph generation unit 124 calculates a weight for each edge included in the k-nearest neighbor graph using the probability distribution of the latent space. In step S35, the path search unit 125 searches for the shortest path from the start node to the end node on the k-nearest neighbor graph in which the edges are weighted.

In step S36, the path search unit 125 defines a cost function having the positions of the nodes included in the shortest path in step S35 as parameters. This cost function is the sum of the maximum flux value, which is the sum of the weights between adjacent nodes on the path, and a constraint term calculated from the structure of the k-nearest neighbor graph after a node movement.

In step S37, the path search unit 125 moves a node included in the path so that the cost function value decreases, using the gradient of the cost function value with respect to the position of the node. The path search unit 125 iteratively moves a node until the cost function value converges. In step S38, the shape prediction unit 126 converts each feature represented by the nodes included in the path optimized in step S37 into shape data by using the decoder 132. The shape prediction unit 126 outputs a shape data string in which the converted shape data is arranged in time series.

As described above, the fourth embodiment has the same effects as those of the third embodiment. Furthermore, the information processing apparatus 100 according to the fourth embodiment adds the constraint term calculated from the structure of the k-nearest neighbor graph after a node movement, to the cost function. Accordingly, the positions of the nodes are adjusted within an appropriate range with reference to the shortest path obtained from the k-nearest neighbor graph. As a result, a natural path is finally obtained, and the prediction accuracy for a deformation process is improved.

### Fifth Embodiment

A fifth embodiment is different from the second to fourth embodiments in the path search method in a latent space. Hereinafter, matters different from the second to fourth embodiments will be mainly described, and description of matters similar to the second to fourth embodiments may be omitted.

An information processing apparatus according to the fifth embodiment may be implemented using the same hardware as in FIG. 2. The information processing apparatus according to the fifth embodiment is able to use the same autoencoder as that illustrated in FIG. 3. The information processing apparatus according to the fifth embodiment may be implemented with the same functional blocks as those in FIG. 8. Therefore, the fifth embodiment will be described below using the same reference numerals as those in FIGS. 2, 3, and 8.

In the third and fourth embodiments, the shortest path is obtained from a k-nearest neighbor graph, and the path is further optimized based on the shortest path. By contrast, the information processing apparatus 100 according to the fifth embodiment sets a certain number of intermediate nodes on a line segment connecting a start node and an end node, and optimizes the path using a cost function with reference to the line segment. Therefore, in the fifth embodiment, the k-nearest neighbor graph is not generated, and the shortest path search on the graph is omitted.

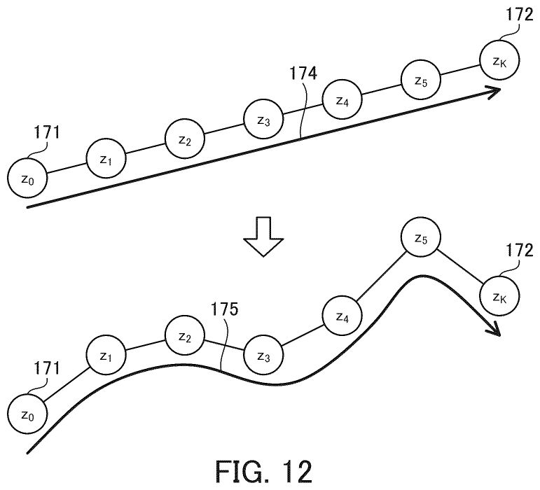

FIG. 12 illustrates an example of optimization of nodes on a line segment. The information processing apparatus 100 draws a line segment connecting a node 171 as a start node and a node 172 as an end node in a latent space. The information processing apparatus 100 sets a certain number of nodes on the line segment as intermediate nodes. For example, the certain number is 1000. The information processing apparatus 100 may set a plurality of nodes at equal intervals on the line segment. Accordingly, the information processing apparatus 100 generates a path 174 from the node 171 to the node 172.

The information processing apparatus 100 moves at least some nodes in the latent space with reference to the path 174 that is the line segment, as in the third embodiment. Here, the information processing apparatus 100 calculates the maximum flux value that is the sum of weights between adjacent nodes, for the path 174. The information processing apparatus 100 calculates the gradient of the maximum flux value with respect to the position of each node, and finely adjusts the position of each node so that the maximum flux value decreases. The information processing apparatus 100 iteratively moves a node until the maximum flux value converges. As a result, the path 174, which is the line segment, is optimized to a path 175, which is a curve.

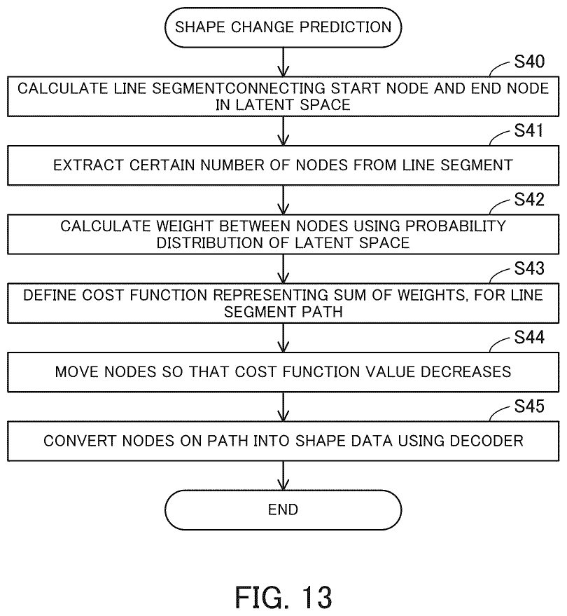

FIG. 13 is a flowchart illustrating a fourth example procedure for the shape change prediction. In step S40, the graph generation unit 124 specifies a start node indicating the shape of a start point and an end node indicating the shape of an end point. The graph generation unit 124 calculates a line segment connecting the start node and the end node in a latent space. In step S41, the graph generation unit 124 extracts a certain number of nodes from the line segment obtained in step S40. The graph generation unit 124 connects adjacent nodes on the line segment by an edge. As a result, a graph representing the line segment path is generated.

In step S42, the graph generation unit 124 calculates a weight for each edge included in the graph of step S41 using the probability distribution of the latent space. The weight is proportional to the length of the edge and inversely proportional to the probability at the midpoint of the edge. In step S43, the path search unit 125 defines a cost function having the positions of the nodes as parameters. The cost function represents the maximum flux value that is the sum of the weights between adjacent nodes on the path.

In step S44, the path search unit 125 moves a node included in the path so that the cost function value decreases, using the gradient of the cost function value with respect to the position of the node. The path search unit 125 iteratively moves a node until the cost function value converges. In step S45, the shape prediction unit 126 converts each feature represented by the nodes included in the path optimized in step S44 into shape data by using the decoder 132. The shape prediction unit 126 outputs a shape data string in which the converted shape data is arranged in time series.

As described above, the information processing apparatus 100 according to the fifth embodiment searches for a path in consideration of the probability distribution of the latent space given by the autoencoder, and converts the path into a shape data string. Accordingly, the predicted deformation process approximates an ideal deformation process that is derived based on expert knowledge, and the prediction accuracy is improved. The information processing apparatus 100 according to the fifth embodiment searches for a path having the minimum maximum flux value, starting from a line segment connecting a start node and an end node. Accordingly, the optimization is performed from the viewpoint of the entire path, and the prediction accuracy is improved. In addition, the shortest path search for the k-nearest neighbor graph may be omitted, and the calculation amount may be reduced.

The disclosed techniques make it possible to improve the prediction accuracy for the deformation process of a molecule.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A non-transitory computer-readable storage medium storing a computer program that causes a computer to perform a process comprising:
generating graph data including a plurality of nodes and a plurality of edges connecting the plurality of nodes in a latent space to which features each corresponding to shape data representing a shape of a molecule and having a smaller number of dimensions than the shape data belong, the plurality of nodes representing different features;
calculating a weight for each edge of the plurality of edges, using a distance in the latent space between two nodes connected by the each edge and a probability distribution of the features in the latent space; and
predicting a deformation process between a first shape corresponding to a first node among the plurality of nodes and a second shape corresponding to a second node among the plurality of nodes by searching for a path in the latent space between the first node and the second node using the weight.

2. The non-transitory computer-readable storage medium according to claim 1, wherein the generating includes converting a plurality of samples of the shape data into a plurality of features by using a trained autoencoder, and generating the graph data in which the plurality of nodes represent the plurality of features obtained by the converting.

3. The non-transitory computer-readable storage medium according to claim 1, wherein the graph data represents a k-nearest neighbor graph in which each of the plurality of nodes is connected to k other nodes in ascending order of the distance, the k being an integer of 2 or more.

4. The non-transitory computer-readable storage medium according to claim 1, wherein the predicting includes searching the graph data for a shortest path that minimizes a sum of weights of edges traversed among the plurality of edges.

5. The non-transitory computer-readable storage medium according to claim 1, wherein the predicting includes identifying a first path from the first node to the second node via one or more third nodes from the graph data, and generating a second path in which at least one of the one or more third nodes has been moved in the latent space, using a sum of weights of edges included in the first path.

6. An information processing method comprising:
generating, by a processor, graph data including a plurality of nodes and a plurality of edges connecting the plurality of nodes in a latent space to which features each corresponding to shape data representing a shape of a molecule and having a smaller number of dimensions than the shape data belong, the plurality of nodes representing different features;
calculating, by the processor, a weight for each edge of the plurality of edges, using a distance in the latent space between two nodes connected by the each edge and a probability distribution of the features in the latent space; and
predicting, by the processor, a deformation process between a first shape corresponding to a first node among the plurality of nodes and a second shape corresponding to a second node among the plurality of nodes by searching for a path in the latent space between the first node and the second node using the weight.

7. An information processing apparatus comprising:
a memory configured to store graph data including a plurality of nodes and a plurality of edges connecting the plurality of nodes in a latent space to which features each corresponding to shape data representing a shape of a molecule and having a smaller number of dimensions than the shape data belong, the plurality of nodes representing different features; and
a processor coupled to the memory and the processor configured to:
calculate a weight for each edge of the plurality of edges, using a distance in the latent space between two nodes connected by the each edge and a probability distribution of the features in the latent space; and
predict a deformation process between a first shape corresponding to a first node among the plurality of nodes and a second shape corresponding to a second node among the plurality of nodes by searching for a path in the latent space between the first node and the second node using the weight.
